(19) United States
(12) Patent Application Publication
(10) Pub. No.: US 2007/0121304 A1
(43) Pub. Date: May 31, 2007

(54) Printed circuit board with guidance portion for mounting component

(75) Inventors: Naofumi Okayama, Echizen-city (JP); Yoshiyuki Miyajima, Echizen-city (JP); Kiyozumi Gotou, Echizen-city (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: ORION ELECTRIC CO., LTD., Echizen-city (JP)

(21) Appl. No.: 11/604,336

(22) Filed: Nov. 27, 2006

(30) Foreign Application Priority Data
Nov. 28, 2005 (JP) 2005-342505

(51) Int. Cl. H05K 7/00

(52) U.S. Cl. 361/760

(57) ABSTRACT

The invention provides a printed circuit board capable of preventing an electronic component from tilting or uplifting without adopting special structures in an existing electronic component. The printed circuit board has an engagement portion and terminal holes and for mounting an electronic component, comprising narrowed portions and having substantially the same width as the mounting leg portions and connecting terminals of the electronic component, and guidance portions having a width wider than the narrowed portion, wherein the mounting leg portions and connecting terminals are inserted to the guidance portion, and the electronic component is moved via sliding motion, by which the mounting leg portions and the connecting terminals are supported tightly in the narrowed portion. Thus, it becomes possible to prevent the displacement or tilt of the electronic component.

The present application is based on and claims priority of Japanese patent application No. 2005-342505 filed on Nov. 28, 2005, the entire contents of which are hereby incorporated by reference.

### BACKGROUND OF THE INVENTION

1. Field of the Invention

The present invention relates to a printed circuit board with a guidance portion for mounting components, capable of preventing the electronic components from being tilted or lifted without adopting special structures in existing electronic components.

1. Description of the Related Art

Conventionally, various methods have been disclosed regarding the methods for mounting electronic components to printed circuit boards constituting electronic devices.

For example, Japanese Patent Application Laid-Open Publication No. 2004-319204 (patent document 1) discloses an arrangement in which small U-shaped cut-out parts and large U-shaped cut-out parts having stepped shapes are formed on leg portions of a connection terminal fitting, and having long rectangular holes for inserting the leg parts and rectangular holes for sliding the inserted leg parts formed on the printed circuit board.

Further, as illustrated in FIGS. 5 through 7, a conventional structure is used widely in which engagement portions and terminal holes for mounting a connecting jack, which is one example of an electronic component, is formed on the printed circuit board, and by inserting all the connecting terminals of the connecting jack, including mounting leg portions having engagement claws integrally formed thereto and connecting terminals subjected to forming process, to the corresponding engagement portions and terminal holes, it becomes possible to engage and fix to the printed circuit board the engagement claws and connecting terminals curved via the forming process.

However, the method disclosed in patent document 1 requires a special fitting for the connecting terminal to be formed, which causes manufacturing costs to be increased. Furthermore, when adopting the general method illustrated in FIGS. 5 through 7, if the engagement portions and terminal holes are widened to facilitate the mounting operation of the electronic component, clearances will be formed on the sides that may cause the electronic component to be mounted unstably, but on the other hand, if the engagement portions and terminal holes are narrowed down to prevent unstable mounting, the mounting operation of the electronic component may become difficult, and in addition, the curved portion of the connecting terminal formed via the forming process may apply stress to the printed circuit board as illustrated in FIG. 7B, causing tilt or displacement of the electronic component as a result.

### SUMMARY OF THE INVENTION

The present invention aims at solving the above-mentioned problems, by providing a printed circuit board having a guidance portion for mounting components, capable of facilitating the mounting operation of electronic components and preventing unstable mounting or lifting of the electronic components without requiring any special structure to be provided on the electronic components.

The first aspect of the present invention provides a printed circuit board with a guidance portion for mounting a component comprising an electronic component with a mounting leg portion and a connecting terminal; a printed circuit board for mounting the electronic component, the printed circuit board having a terminal hole and an engagement portion for inserting the connecting terminal and the mounting leg portion, with an engagement claw disposed at least on an end of the mounting leg portion inserted to the engagement portion to be engaged with a rear surface of the printed circuit board, the electronic component being supported on the printed circuit board in a fall-proof manner by the engagement claw; wherein the terminal hole and the engagement portion are formed to have a long narrow shape enabling the mounting leg portion and the connecting terminal to be moved in sliding motion therein, at least the engagement portion has a narrowed portion with substantially the same width as the mounting leg portion and a guidance portion connected to the narrowed portion and capable of having the engagement claw inserted thereto, and wherein the engagement claw is engaged with the printed circuit board by having the electronic component with the engagement portion inserted to the guidance portion slide toward the narrowed portion.

According to the arrangement of aspect 1, upon forming a terminal hole and an engagement portion to the printed circuit board for mounting the electronic component, the terminal hole for mounting the connecting terminal of the electronic component is formed to have a long narrow shape enabling the connecting terminal to be moved in sliding motion therein, and in addition, the engagement portion formed as a hole having substantially the same width as the mounting leg portion of the electronic component is connected with the guidance portion having substantially the same width as the engagement claw formed on the mounting leg portion of the electronic component, so that when the electronic component is mounted on the printed circuit board, the mounting leg portion is inserted to the guidance portion and the connecting terminal is inserted to the terminal hole before being moved in sliding motion therein, by which the mounting leg portion is inserted to the engagement portion, and the electronic component is fixed to the printed circuit board via the engagement claw.

The second aspect of the present invention provides a printed circuit board with a guidance portion for mounting a component according to aspect 1, wherein the electronic component comprises a plurality of connecting terminals, having a fall-proof projection integrally formed on an end of at least a portion of the connecting terminals, and wherein the terminal hole for inserting the connecting terminal is composed of a narrowed portion capable of having the connecting terminal inserted thereto, and a guidance portion connected to the narrowed portion and capable of having at least the projection inserted thereto.

According to the arrangement of aspect 2, the electronic component having a fall-proof projection formed on a portion of the plurality of connecting terminals to prevent the electronic component from falling from the printed circuit board is engaged via the projection with the printed circuit board having a narrowed portion capable of having the connecting terminal inserted thereto and a guidance portion connected to the narrowed portion and capable of having the projection inserted thereto.

A printed circuit board with a guidance portion for mounting a component according to the third aspect of the present invention provides a printed circuit board with a guidance portion for mounting a component according to aspect 1 or aspect 2, wherein at least one of the plurality of terminal holes has an engaging projection formed between the narrowed portion and the guidance portion for engaging and restricting the mounting leg portion or the connecting terminal slid toward the narrowed portion from moving back toward the guidance portion.

According to the arrangement of aspect 3, at least one of the plurality of terminal holes has an engaging projection formed between the narrowed portion and the guidance portion for engaging and fixing at least either the mounting leg portion or the connecting terminal after the electronic component is slid into position.

### BRIEF DESCRIPTION OF THE DRAWINGS

FIG. 1 is a partially cutaway plan view showing engagement portions and terminal holes for an electronic component formed on a printed circuit board according to the present embodiment;

FIG. 2 is a perspective view of the same showing the state prior to mounting a connecting jack to the printed circuit board;

FIG. 3 is a perspective view of the same showing the state after mounting the connecting jack to the printed circuit board;

FIG. 4 is a perspective view of the same showing the bottom surface of the printed circuit board of FIG. 3;

FIG. 5 is a partially cutaway plan view showing engagement portions and terminal holes formed on a printed circuit board used widely according to the prior art;

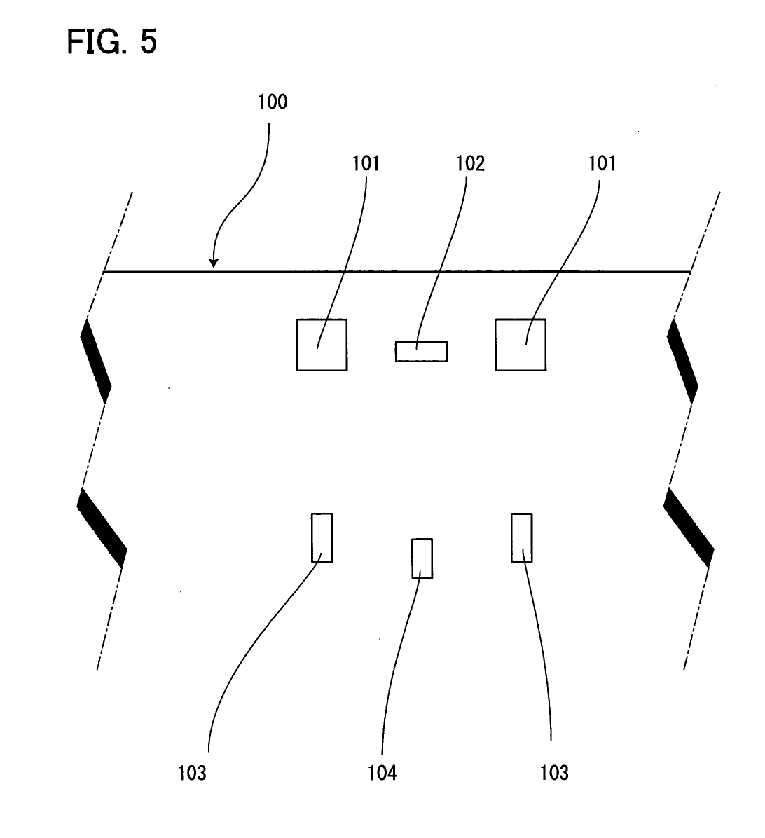

FIG. 6A is a front view of the same showing the state in which a connecting jack is mounted to the printed circuit board of FIG. 5, and FIG. 6B is a bottom view thereof; and

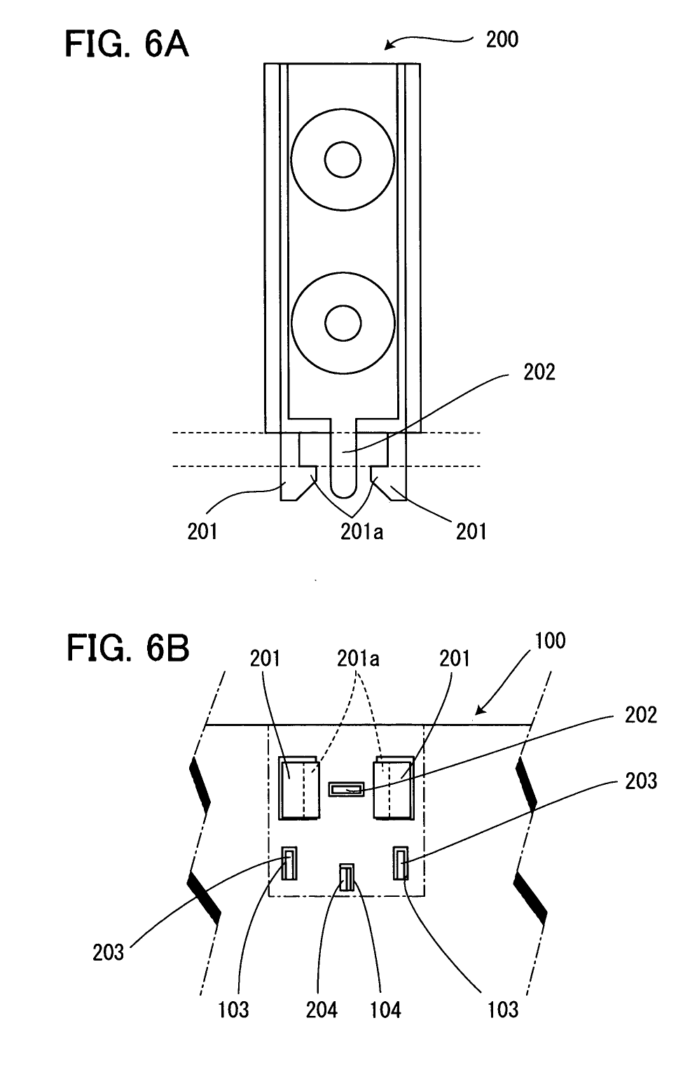

FIG. 7A is a rear view of the same showing the state in which the connecting jack is mounted to the printed circuit board of FIG. 5, and FIG. 7B is a bottom view showing the state in which the connecting jack is tilted.

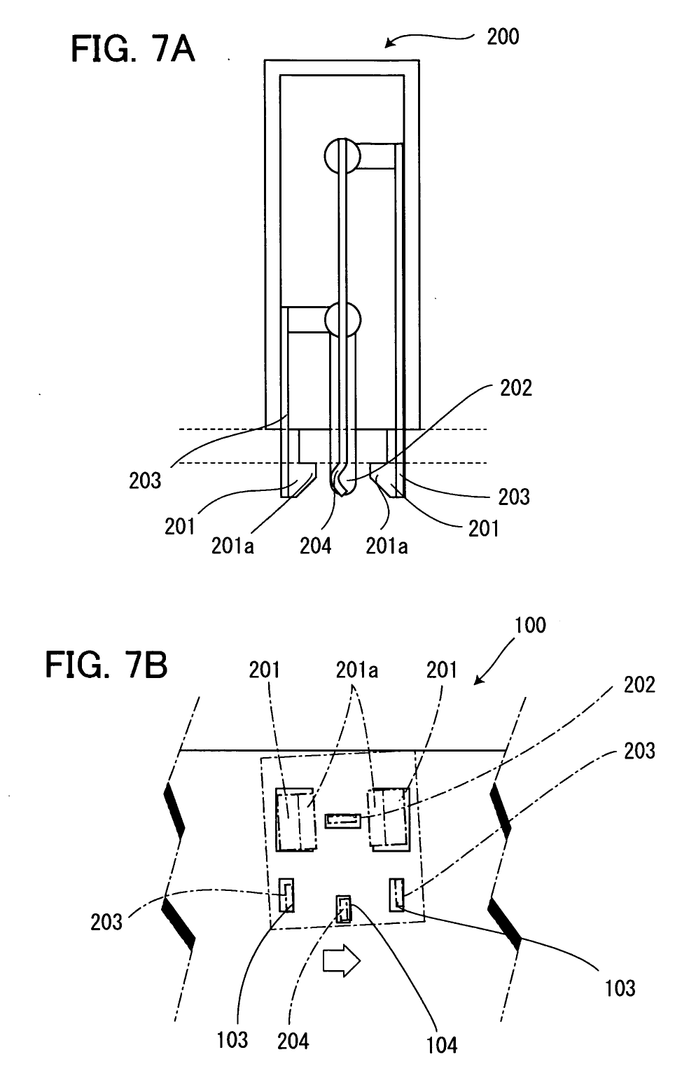

### DETAILED DESCRIPTION OF THE PREFERRED EMBODIMENTS

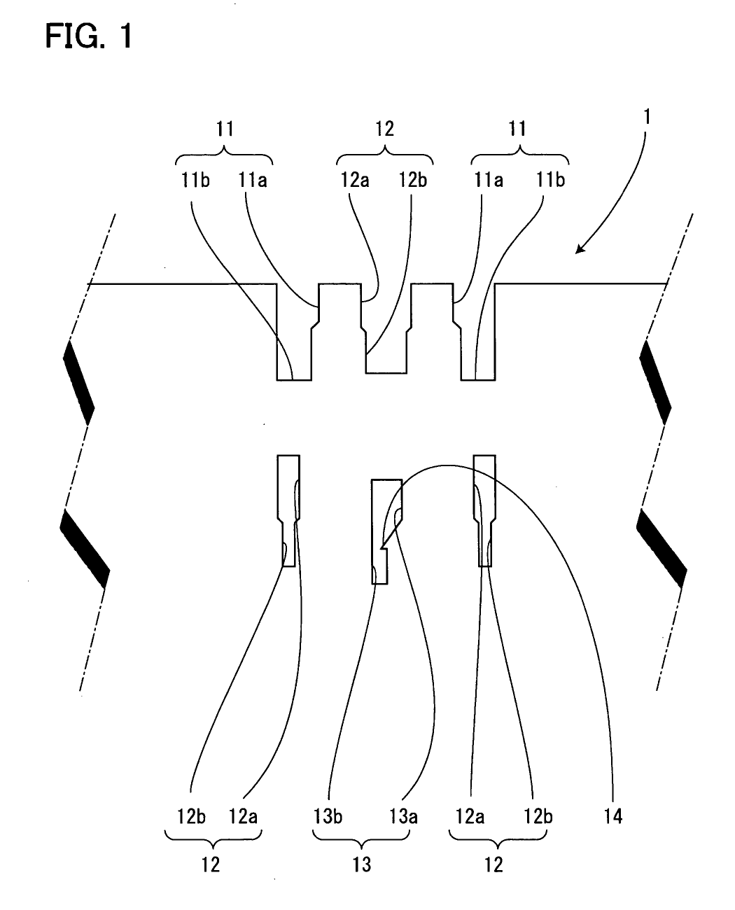

Now, the preferred embodiment for carrying out the present invention will be described with reference to FIGS. 1 through 4. Of course, the present invention is applicable to cases other than the example described in the present embodiment within the scope of the present invention.

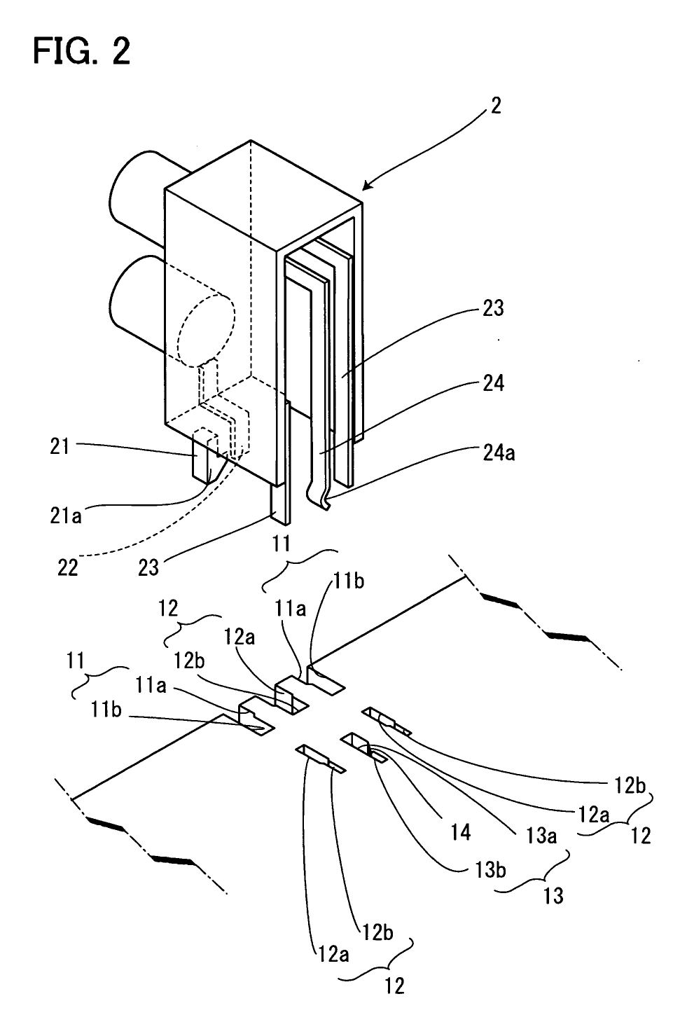

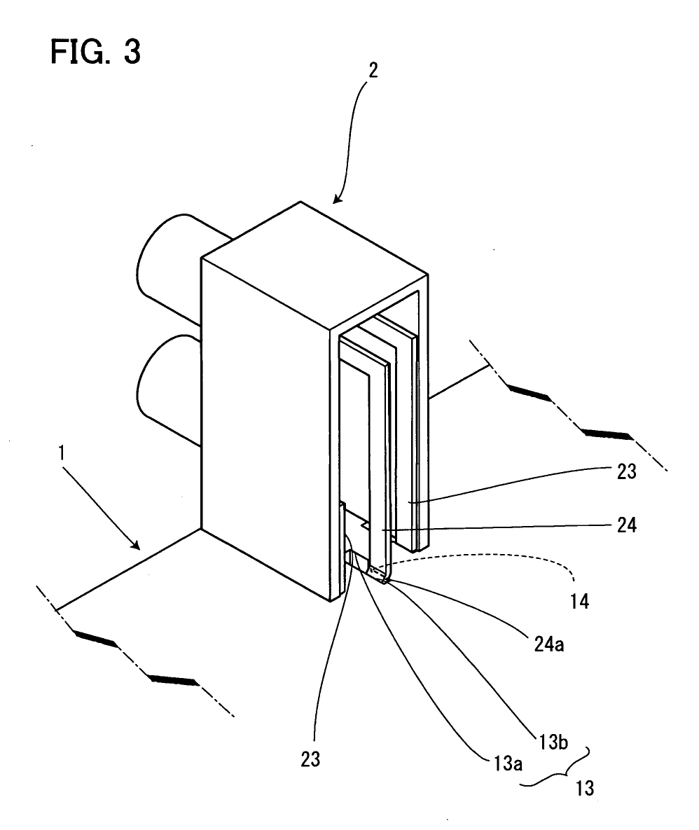

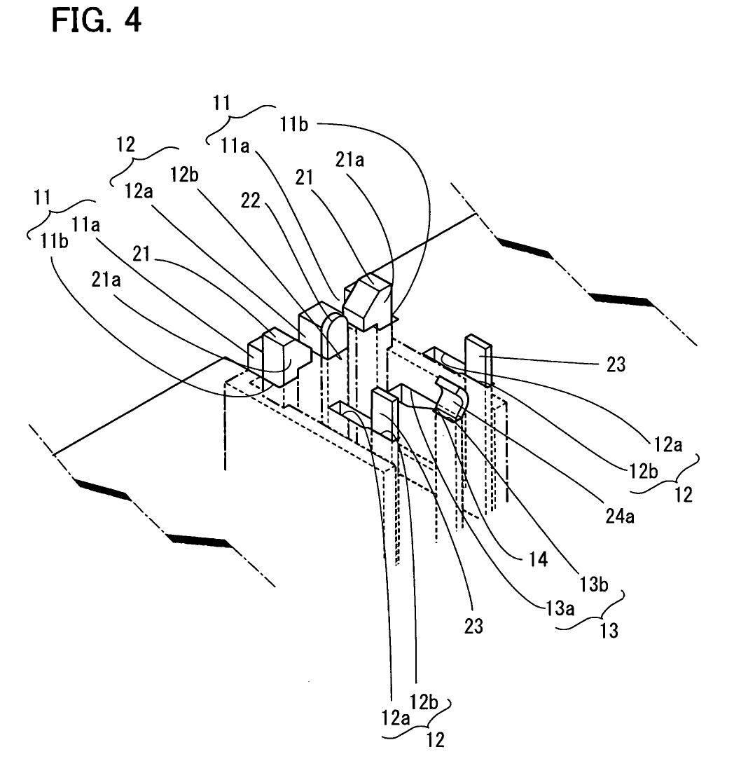

FIGS. 1 through 4 illustrate the preferred embodiment of the present invention, wherein FIG. 1 is a partially cutaway plan view of the printed circuit board illustrating the shapes of engagement portions and terminal holes. FIG. 2 is a perspective view showing the state prior to mounting a connecting jack to the printed circuit board shown in FIG. 1, and FIG. 3 is a perspective view showing the mounted state. FIG. 4 is a perspective view showing the bottom side of the printed circuit board having the connecting jack illustrated in FIG. 3 mounted thereto.

The structure of the printed circuit board according to the present embodiment will now be described with reference to FIG. 1. Reference number 1 denotes a printed circuit board having an electronic circuit printed thereon to be fixed to an interior of a casing of an electronic device. Reference number 11 denotes an engagement portion for receiving the mounting leg portion of a connecting jack which is the electronic component mentioned in detail later, wherein 11a denotes a guidance portion for guiding the mounting leg portions and 11b denotes a narrowed portion for positioning the mounting leg portion. The guidance portion 11a is formed to have an opening opened to the outer side of the printed circuit board 1 so as to facilitate guidance of the mounting leg portion. Reference number 12 denotes a terminal hole for receiving the connecting terminal of the connecting jack, wherein 12a denotes a guidance portion for guiding the connecting terminal and 12b denotes a narrowed portion for positioning the connecting terminal. Reference number 13 denotes a terminal hole for receiving a connecting terminal having been subjected to a forming process as described later, wherein 13a is a guidance portion for guiding the connecting terminal and 13b is a narrowed portion for positioning the connecting terminal. Reference number 14 denotes an engaging projection for engaging the connecting terminal having been subjected to forming process.

Next, the structure of the connecting jack and the process for mounting the connecting jack to the printed circuit board 1 will be described with reference to FIGS. 2 and 3. Reference number 2 denotes a connecting jack being the electronic component. Reference number 21 denotes a mounting leg portion for mounting the same to the printed circuit board 1, and 21a denotes an engagement claw for engaging the mounting leg portion 21 to the printed circuit board 1. Reference numbers 22 and 23 denote connecting terminals for electrically connecting the connecting jack 2 with the printed circuit board 1, reference number 24 is a connecting terminal having been subjected to forming process by which the connecting terminal is curved to prevent the connecting jack 2 from falling, and reference number 24a denotes a curved portion formed via the forming process. FIG. 2 shows the state prior to mounting the connecting jack 2. The mounting leg portion 21 of the connecting jack 2 is inserted to the corresponding guidance portion 11a formed to the printed circuit board 1. Similarly, connecting terminals 22 and 23 are respectively inserted to the corresponding guidance portions 12a, the connecting terminal 24 having been subjected to forming process is inserted to the guidance portion 13a, and thereafter, by sliding the connecting jack 2 rearward, that is, toward the inner direction of the printed circuit board 1, it becomes possible to respectively tightly support the mounting leg portion 21 via the narrowed portion 11b, the connecting terminals 22 and 23 via the narrowed portions 12b, and the connecting terminal 24 having been subjected to forming via the narrowed portion 13b, as illustrated in FIG. 3.

The state in which the connecting jack 2 is mounted on the printed circuit board 1 will now be described with reference to FIG. 4. The mounting leg portions 21 are supported tightly without a clearance in the narrowed portions 11b, and are engaged to the engagement portions 11 via engagement claws 21a. This arrangement prevents the connecting jack 2 from being lifted in the front ward area. Further, since the connecting terminals 22 and 23 are similarly supported tightly without a clearance in the narrowed portions 12b, they will not be unstable in the side directions. Furthermore, by forming a curved portion 24a displaced from the center of the guidance portion and engaged with the projected narrowed portion 13b, it becomes possible to prevent the connecting jack 2 from being lifted in the rearward area. Even further, by engaging the connecting terminal 24 having been subjected to forming with the engaging projection 14 formed between the guidance portion 13a and the narrowed portion 13b, it becomes possible to prevent the connecting jack 2 from falling.

According to the present embodiment having the arrangement described above, the connecting jack 2 is mounted by inserting and sliding the mounting leg portions 21, the connecting terminals 22, 23 and connecting terminal 24 having been subjected to forming process to the corresponding guidance portions 11a, 12a and guidance portion 13a corresponding to the connecting terminal having been subjected to forming process, by which the mounting leg portions 21, the connecting terminals 22, 23 and connecting terminal 24 having been subjected to forming process are inserted to and supported tightly in the narrowed portions 11b, 12b and the narrowed portion 13b corresponding to the connecting terminal having been subjected to forming process. Since all the parts are fit tightly to the narrowed portions without a clearance formed at the sides with respect to the sliding direction of the connecting jack 2, the connecting jack 2 will not be displaced sideways. At this time, since the engagement claws 21a are engaged with the engagement portions 11, it becomes possible to prevent the connecting jack 2 from being lifted at the front ward area with respect to the sliding direction and also prevent the connecting jack 2 from falling toward the sliding direction. Furthermore, since the narrowed portion 13b corresponding to the connecting terminal having been subjected to forming process is formed to correspond to the curved portion 24a, the curved portion 24a can be fit to the narrowed portion 13b, thereby preventing the curved portion 24a from applying stress to the printed circuit board 1, preventing the connecting jack 2 from being displaced or tilted, and also preventing the connecting jack 2 from being lifted at the depth area with respect to the sliding direction. Moreover, since the engaging projection 14 is formed between the guidance portion 13a and the narrowed portion 13b corresponding to the connecting terminal having been subjected to forming, the connecting terminal 24 having been subjected to forming is engaged with the engaging projection 14, by which the connecting terminal 24 having been subjected to forming is prevented from sliding back toward the guidance portion 13a, and the connecting jack 2 is prevented from falling to the direction opposite to the sliding direction. That is, it becomes possible to realize at low costs, without additionally providing special arrangements to the conventional connecting jack 2, a printed circuit board 1 having a mounting portion for a connecting jack 2 formed as mentioned in the present embodiment, capable of preventing the connecting jack from being displaced or tilted in the front-rear or side directions with respect to the sliding direction during the mounting process, and also preventing the connecting jack 2 from falling when a plug not shown is inserted to or removed from the connecting jack 2.

The preferred embodiment of the present invention has been described, but the present invention is not restricted to the example disclosed in the embodiment, and various modifications are possible within the scope of the present invention. For example, the electronic component according to the present embodiment is a connecting jack 2, but it is not restricted thereto, and the present invention can be applied to other electronic components having mounting leg portions and connecting terminals. Furthermore, the guidance portion 11a is designed to have an opening opened toward the outer direction so as to facilitate guidance of the mounting leg portion 21 of the connecting jack 2, but it is not restricted thereto, and the guidance portion can also be designed to have a hole with a size large enough to allow the engagement claw 21a of the mounting leg portion 21 to be inserted thereto. Furthermore, the engaging projection 14 is formed on the mounting portion having been subjected to forming, but it is not restricted thereto, and the engaging projection can be formed on other mounting portions or all the mounting portions.

The effects of the present invention are as follows.

The first aspect of the present invention provides a printed circuit board with a guidance portion for mounting a component comprising an electronic component with a mounting leg portion and a connecting terminal; a printed circuit board for mounting the electronic component, the printed circuit board having a terminal hole and an engagement portion for inserting the connecting terminal and the mounting leg portion, with an engagement claw disposed at least on an end of the mounting leg portion inserted to the engagement portion to be engaged with a rear surface of the printed circuit board, the electronic component being supported on the printed circuit board in a fall-proof manner by the engagement claw; wherein the terminal hole and the engagement portion are formed to have a long narrow shape enabling the mounting leg portion and the connecting terminal to be moved in sliding motion therein, at least the engagement portion has a narrowed portion with substantially the same width as the mounting leg portion and a guidance portion connected to the narrowed portion and capable of having the engagement claw inserted thereto, and wherein the engagement claw is engaged with the printed circuit board by having the electronic component with the engagement portion inserted to the guidance portion slide toward the narrowed portion. According to aspect 1, the mounting leg portion and the connecting terminal can be inserted easily via the guidance portion, and by sliding the component until it is tightly supported by the narrowed portion, the electronic component can be positioned in the predetermined mounting position. Since the narrowed portion has substantially the same width as the mounting leg portion or the connecting terminal, it prevents the electronic component from being unstable in the side directions with respect to the sliding direction. Moreover, since the engagement claw of the mounting leg portion is engaged with the engagement portion, the electronic component is prevented from being lifted up by the pressure applied to the electronic component in the sliding direction.

The second aspect of the present invention provides the printed circuit board with a guidance portion for mounting a component according to the first aspect, wherein the electronic component comprises a plurality of connecting terminals, having a fall-proof projection integrally formed on an end of at least a portion of the connecting terminals, and wherein the terminal hole for inserting the connecting terminal is composed of a narrowed portion capable of having the connecting terminal inserted thereto, and a guidance portion connected to the narrowed portion and capable of having at least the projection inserted thereto. According to this arrangement, the mounting portions are designed to correspond to the shape of the connecting terminal, so it becomes possible to prevent the displacement of the electronic component caused by the stress generated when the projection on the connecting terminal formed via the forming process or the like contacts the printed circuit board. Furthermore, the projection can be engaged with the printed circuit board by forming a guidance portion having substantially the same width as the projection and a narrowed terminal hole.

The third aspect of the present invention provides the printed circuit board with a guidance portion for mounting a component according to aspect 1 or aspect 2, wherein at least one of the plurality of terminal holes has an engaging projection formed between the narrowed portion and the guidance portion for engaging and restricting the mounting leg portion or the connecting terminal slid toward the narrowed portion from moving back toward the guidance portion. According to this arrangement, the electronic component can be prevented from falling off by having the mounting leg portion and the connecting terminal inserted to the guidance portion and slide to the deepest position, where at least one mounting leg portion or connecting terminal is engaged with the engaging projection, preventing the component from sliding back toward the guidance portion.

What is claimed is:

1. A printed circuit board with a guidance portion for mounting a component comprising:
an electronic component with a mounting leg portion and a connecting terminal;
a printed circuit board for mounting the electronic component, the printed circuit board having a terminal hole and an engagement portion for inserting the connecting terminal and the mounting leg portion, with an engagement claw disposed at least on an end of the mounting leg portion inserted to the engagement portion to be engaged with a rear surface of the printed circuit board, the electronic component being supported on the printed circuit board in a fall-proof manner by the engagement claw; wherein the terminal hole and the engagement portion are formed to have a long narrow shape enabling the mounting leg portion and the connecting terminal to be moved in sliding motion therein, at least the engagement portion has a narrowed portion with substantially the same width as the mounting leg portion and a guidance portion connected to the narrowed portion and capable of having the engagement claw inserted thereto, and wherein the engagement claw is engaged with the printed circuit board by having the electronic component with the engagement portion inserted to the guidance portion slide toward the narrowed portion.

2. The printed circuit board with a guidance portion for mounting a component according to claim 1, wherein the electronic component comprises a plurality of connecting terminals, having a fall-proof projection integrally formed on an end of at least a portion of the connecting terminals, and wherein the terminal hole for inserting the connecting terminal is composed of a narrowed portion capable of having the connecting terminal inserted thereto, and a guidance portion connected to the narrowed portion and capable of having at least the projection inserted thereto.

3. The printed circuit board with a guidance portion for mounting a component according to claim 1, wherein at least one of the plurality of terminal holes has an engaging projection formed between the narrowed portion and the guidance portion for engaging and restricting the mounting leg portion or the connecting terminal slid toward the narrowed portion from moving back toward the guidance portion.

4. The printed circuit board with a guidance portion for mounting a component according to claim 2, wherein at least one of the plurality of terminal holes has an engaging projection formed between the narrowed portion and the guidance portion for engaging and restricting the mounting leg portion or the connecting terminal slid toward the narrowed portion from moving back toward the guidance portion.
